(19) United States
(12) Patent Application Publication
(10) Pub. No.: US 2021/0211073 A1
(43) Pub. Date: Jul. 8, 2021

(54) VIBRATIONAL ENERGY RECOVERY SYSTEM

(71) Applicants: UNIVERSITE SAVOIE MONT BLANC, CHAMBERY CEDEX (FR); INSTITUT NATIONAL DES SCIENCES APPLIQUEES DE LYON, VlLLEURBANNE (FR)

(72) Inventors: Adrien BADEL, LESCHERAINES (FR); Fabien FORMOSA, ANNECY-LE-VIEUX (FR); Thomas HUGUET, BRAX (FR)

(21) Appl. No.: 17/059,111

(22) PCT Filed: May 15, 2019
(86) PCT No.: PCT/FR2019/051111

§ 371 Date: Nov. 25, 2020

(30) Foreign Application Priority Data
May 29, 2018 (FR) 1870615

(51) Int. Cl. H02N 2/18; H01L 41/113

(52) U.S. Cl. CPC H02N 2/186; H01L 41/1134

(57) ABSTRACT

The present disclosure concerns a mechanical vibration energy harvesting device including a bistable spring blade structure in a frame, and a sliding joint at the level of a wall of the frame between said structure and at least one mechanical-to-electrical device external to the frame.

The present patent application claims the priority benefit of French patent application FR18/70615 which is herein incorporated by reference.

### BACKGROUND

The present disclosure generally concerns energy harvesters and, more particularly, vibration energy harvester devices, capable of generating electricity from mechanical vibrations. The present invention particularly applies to the generation of energy by equipment capable of vibrating, for example, air conditioning ducts in a building, computers in operation, industrial machines, vehicle motors, transport infrastructures, etc.

### DISCUSSION OF THE RELATED ART

It is long known that it is possible to harvest energy from vibrations of a mechanical system. Certain mechanical-to-electrical converters or vibration harvesters use piezoelectric elements to convert mechanical energy originating from the vibrations into electricity.

An example of a mechanical vibration energy harvesting electric generator is described in document WO A 2011/073591 (B9966PCT).

Document US-A-2008/0100181 describes a non-linear piezoelectric mechanical-to-electrical generator system and method.

Document US-A-2012/0119620 describes a device and a method of multistage force amplification of piezoelectric stacks.

Document WO-A-2002/029965 describes a piezoelectric energy harvester.

### SUMMARY

There is a need to improve mechanical-to-electrical converters in tams of industrialization.

There also is a need to improve mechanical vibration energy harvesting electric generators in terms of reliability.

An embodiment overcomes all or part of the disadvantages of usual vibration energy harvesters.

An embodiment provides a mechanical vibration energy harvesting device including a bistable spring blade structure in a frame, and a sliding joint at the level of a wall of the frame between said structure and at least one mechanical-to-electrical device external to the frame, the blade structure comprising at least two blades parallel to each other.

According to an embodiment, said sliding joint is obtained by an element sliding in said wall and coupling said structure to said conversion device.

According to an embodiment, said sliding joint is obtained by a defamation of said wall between said structure and said conversion device.

According to an embodiment, the conversion device is coupled to a fixed point with respect to the frame.

According to an embodiment, at least one mass is attached in the central portion of the blade structure.

According to an embodiment, the blade structure is buckled between said frame and said sliding joint.

According to an embodiment, the conversion device comprises a piezoelectric element in a direction approximately perpendicular to the direction of the blade structure.

According to an embodiment, the conversion device comprises a frame in the form of a double arch, the middles of the arches being respectively connected to the sliding joint and to the fixed point.

An embodiment provides an electric power generation system comprising equipment submitted to mechanical vibrations and a mechanical vibration energy harvesting device.

According to an embodiment, the device is attached to the equipment.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a very simplified view illustrating the operating principle of a mechanical vibration energy harvesting electric generator, of bistable type;

FIG. 2 is a cross-section view schematically illustrating an embodiment of a device of vibration energy harvesting and conversion into electric energy.

FIG. 3 is a partial simplified perspective view of an embodiment of a sliding joint between a blade structure and a mechanical-to-electrical conversion device;

FIG. 4 is a very simplified cross-section view of another embodiment of a device of vibration energy harvesting and of conversion into electric energy;

FIG. 5 is a partial simplified view of another embodiment of a sliding joint between a blade structure and a mechanical-to-electrical conversion device; and

FIG. 6 is an enlarged view of an embodiment of an energy conversion device adapted to the described embodiments of energy harvesters.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the system, equipment, device or environment, supplying the vibration energy (the vibrations) has not been detailed, the described embodiments being compatible with usual sources of vibrations in applications of conversion into electric energy. Further, what use is made of the harvested electric energy has not been detailed either, the described embodiments being here again compatible with usual applications of energy harvesters and of conversion into electricity.

Unless indicated otherwise, when reference is made to two elements connected or attached together, this signifies a direct connection without any intermediate elements other than a binder such as glue, welding, or screwing, and when reference is made to two elements associated or coupled together, this signifies that these two elements can be directly coupled or they can be coupled via one or more other elements.

In the following disclosure, unless otherwise specified, when reference is made to absolute positional qualifiers, such as the tams “front”, “back”, “top”, “bottom”, “left”, “right”, etc., or to relative positional qualifiers, such as the tams “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

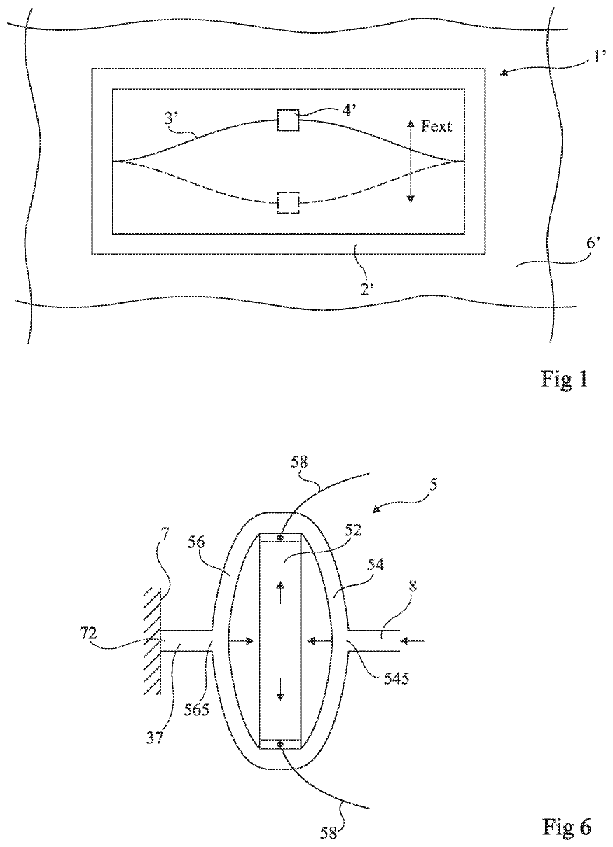

FIG. 1 is a very simplified view illustrating the operating principle of a mechanical vibration energy harvesting electric generator 1′, of bistable type.

Generator 1′ comprises a support and protection package 2′, of generally parallelepipedal shape, capable of being assembled on a vibrating surface 6′ of equipment likely to vibrate. In this example, external vibrations are capable of exerting, on package 2′, an excitation, the effect of which may be schematically represented by a force of direction Fext. Package 2′ contains a spring blade 3′ having its two ends bearing, in compression, on two opposite lateral surfaces of the package. The two bearing points of blade 3′ on package 2′ are placed along an axis substantially orthogonal to direction Fext of the vibrations. A mass 4′ is attached to blade 3′, substantially in its middle. Blade 3′, in compression between its two ends, and mass 4′, define a non-linear or bistable system which may, under the effect of external vibrations, pass from one to the other of two stable positions of equilibrium (respectively shown in full line and in dotted lines in the drawing). The system may also oscillate around each of the two positions of equilibrium. A piezoelectric-type mechanical-to-electrical converter (not shown) is provided to convert the motion of blade 3′ and of mass 4′ into electric energy.

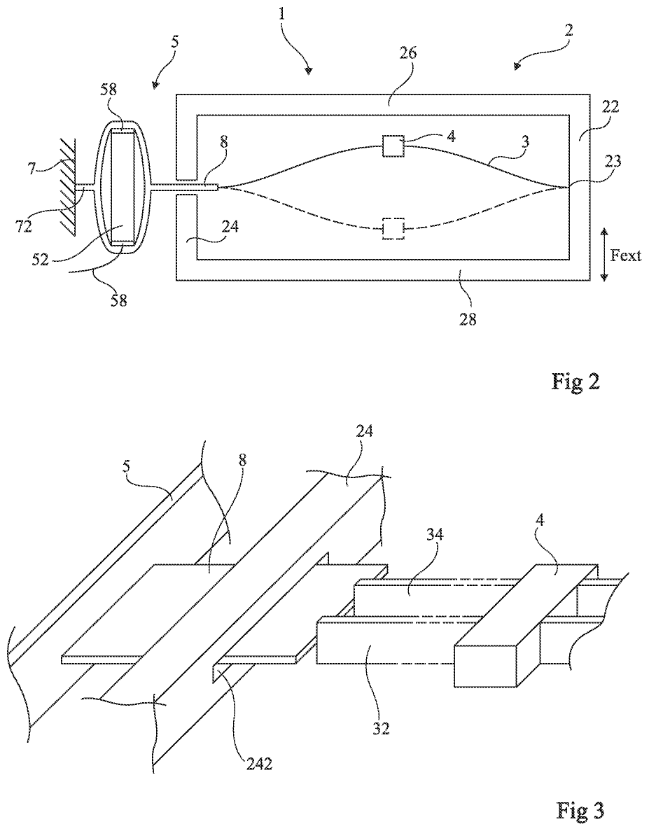

FIG. 2 is a very simplified planar view of an embodiment of a device 1 of vibration energy harvesting and of conversion into electric energy.

According to the described embodiments, energy harvesting device 1 comprises a support package provided with a rigid frame 2, famed of walls 22, 24, 26, 28. The package is for example closed by two plates (not shown), on either side of frame 2, to protect the inside from dust or the like.

A bistable spring blade structure 3, associated with at least one mass 4, forms the vibration energy harvesting mechanism. According to the described embodiments, the spring blade structure is a structure comprising two blades parallel to each other, for example, of the type described hereafter in relation with FIG. 3.

One end of blade structure 3 is attached to a side 22 of the frame (point 23). The other end of structure 3 is coupled to an element 8, translatably assembled through the opposite wall 24 of frame 2. Element 8 is intended to slide through wall 24 in a direction approximately parallel to the median direction of bistable structure 3.

Element 8 rigidly couples blade structure 3 to a mechanical-to-electrical energy conversion device 5. Device 5 comprises a piezoelectric element 52 strained, in the shown example, by a frame, generally called flextensor, here in the form of a double arch 54, 56, or of a diamond. Device 5 is, on the side opposite to element 8, coupled to a fixed point 72, for example, of a chassis 7, with respect to wall 22 of frame 2. In other words, the distance between the end of blade structure 3 and point 72 is constant. This enables to preserve the bistable operation of the harvester despite the sliding joint through wall 24. For example, chassis 7 forms part of a second frame rigidly coupled to frame 2.

Thus, it is provided to place conversion device 5, based on a piezoelectric element, outside of package frame 2. An advantage is that this avoids a passing of conductive wires 58 through the frame walls.

FIG. 3 is a partial simplified perspective view of an embodiment of a sliding element 8 of a sliding joint of a blade structure 3 to a device 5. FIG. 3 also illustrates an embodiment of blade structure 3.

According to this embodiment, structure 3 is famed of two blades 32 and 34 parallel to each other. Mass 4 is attached to the two blades in their middle. An advantage of a double-blade structure is that this avoids a twisting of the blade structure and constrains the oscillation direction.

Preferably, the space between the two blades 32 and 34 is maintained constant. In the example of FIG. 3, this space is maintained constant by the respective attachments of the blades to mass 4, to the frame (point 23) for one end of the structure, and to element 8 for the other end.

According to an embodiment shown in FIG. 3, element 8 has the shape of a plate arranged perpendicularly to blades 32 and 34. Element 8 is assembled to slide in a port 242 of edge 24 of the frame to be coupled to device 5.

An advantage of this embodiment is that a twisting of the system is avoided.

According to another embodiment, element 8 is a cylindrical rod slidably assembled in wall 24. Preferably, to avoid any twisting of blade structure 3, a rod having an oval cross-section will be preferred to a rod having a round cross-section.

Any other type of sliding joint from a kinematic viewpoint (in translation along the axis of blade structure 3) with no rotation (to avoid a twisting of bistable structure 3) may be appropriate.

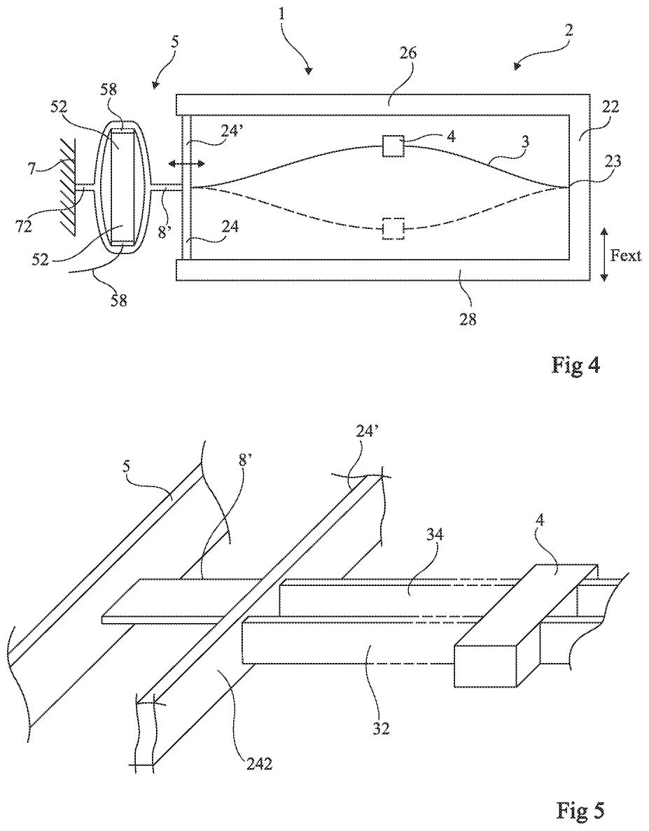

FIG. 4 is a very simplified planar view of another embodiment of a device 1 of vibration energy harvesting and of conversion into electric energy.

It should be noted that, as for FIG. 2, the structure with two parallel blades is not detailed in FIG. 4, for drawing simplification purposes. However, be it in the embodiment of FIG. 2 or in that of FIG. 4, a structure with two blades parallel to each other is provided.

As compared with the embodiment of FIG. 2, the sliding joint between blade structure 3 and electric energy conversion device 5 is not properly sliding, but is obtained by a flexible wall 24′ between blade structure 3 and device 5. In the example of FIG. 4, this is schematized by a wall 24′ thinner than the other walls 22, 26, and 28 of package frame 2. However, the same effect may for example be obtained with a wall 24′ made of a different material. Blade structure 3 on one side and an element 8′ for coupling device 8 to wall 24′ bear, in this embodiment, directly against wall 24′.

An advantage of such a sliding joint with no effective sliding is that frictions are avoided, which optimizes the axial transmission of efforts.

FIG. 5 is a partial simplified perspective view of a sliding joint with no effective sliding between a blade structure 3 and a device 5.

According to this example, the two blades 32 and 34 directly bear by their respective ends on the side of device 5 against wall 24′. Similarly, element 8′ directly bears against wall 24′.

The buckling of the blade structure to give it a bistable character is performed, for example, by straining sides 26 and 28 of frame 2 (the two large sides in the example of FIG. 2) towards the outside, that is, by drawing them away from each other. This causes a shortening between walls 22 and 24 (FIG. 2), respectively 22 and 24′ (FIG. 4) and, since the distance between points 23 and 7 is fixed, a buckling of the structure.

Other solutions may be provided to place the blade structure in buckling position, for example, by causing a lengthening of blade structure 3.

Preferably, the two bearing points 23 and 7 of the obtained system are placed along an axis substantially orthogonal to the expected direction Fext of the vibrations.

FIG. 6 is an enlarged view of an embodiment of an energy conversion device 5 adapted to the described energy harvesting embodiments.

A structure with two blades parallel to each other and with a mass, preferably in central position along the structure length, has many advantages.

The two blades and the fact for the interval between them to be fixed prevent any rotation of the structure along an axis perpendicular to the plane of the system, particularly at the level of mass 4 (or of the masses for the case where a plurality of masses are provided).

Further, this limits any rotating motion at the level of the sliding joint, be it formed according to the embodiment of FIG. 3 or according to that of FIG. 5. Indeed, the median position of the structure, of unstable equilibrium between its two stable positions, is planar (in an imaginary plane parallel to the planes containing the blades), which forces the deformation of the sliding joint along the axis (the median longitudinal direction) of the blades.

Accordingly, the presence of two parallel blades eases the coupling with the sliding joint by limiting mechanical motions thereon. The middle of arches 54 and 56 is coupled, for one of them, to element 8 and, for the other, to housing 7, preferably via a rigid aim 37. The ends of arches 54 and 56 are attached to the ends of piezoelectric element 52 (for example, a stack of interdigited piezoelectric plates, a piezoelectric bar, or any other adapted piezoelectric structure). The couplings 545 and 565 of the middles of arches 54 and 56 to element 8 and to housing 7, are for example rigid (gluing or welding) or formed via ball joints. The end electrodes of piezoelectric element 52 are coupled, by conductive wires 58 to electric/electronic circuits (not shown) for shaping the captured electric signal.

The piezoelectric effect is obtained by deforming (crushing, releasing) arches 54 and 56 from their median portions (connections 545 and 565), which causes a strain (extension, compression) of piezoelectric element 52 and generates electricity. In FIG. 6, arrows illustrate the strain when the system passes through the median (unstable) position. Piezoelectric element 52 is strained in extension under the effect of the bringing of points 545 and 565 towards each other, which causes an elongation of the frame.

It should be noted that the active direction of piezoelectric element 52 is approximately perpendicular to the direction of blade structure 3, and thus approximately parallel to the vibration direction.

It could have been devised to interpose, in line with a spring blade, a piezoelectric element. However, this would generate too much twisting strain thereon. An advantage of the described conversion devices is that piezoelectric element 52 is protected, arches 54 and 56 providing a non-square diamond frame shape having piezoelectric element 52 attached in a diagonal thereof.

The kinematics of device 1 in operation is the following. Starting from one of the two stable positions, for example, that illustrated in full line in FIG. 2, a displacement of the assembly of blades 3/mass 4 towards the other stable position (dotted line in FIG. 2) generates a crushing of arches 54 and 56 of device 5 to pass the median position, which results in a lengthening of piezoelectric element 52, which causes the generation of electricity. The system relaxes when reaching the other stable position. Frame 2 and housing 7 are secured, for example, screwed or glued, to the vibrating equipment (6′, FIG. 1). The vibrations cause an oscillation of the system between the two stable positions, and thus the generation of electricity.

Although an embodiment with a single conversion device has been disclosed, two devices 5 (or even more) may be provided one after the other between element 8 and fixed point 72.

An advantage of the described embodiments is that it is now possible to design, form, and assemble bistable oscillator 3-4 and energy converter 5 separately, which provides more flexibility in tams of design and of implementation. The system is further thus made modular.

Another advantage of the described embodiments is that the robustness of the device obtained by decreasing the strain on the electric connections of converter 5 is improved. Indeed, the latter is no longer submitted to oscillations with respect to the axis, linked to the buckling as would be the case by placing it inside of frame 2, but, due to the presence of a bimetal (or parallel multiple blades), is only submitted to axial displacements. Thus, the couplings (weldings) of the electric connections are preserved.

As an example, the blade(s) may be formed from a steel band having a width in the order of from 5 to 50 mm, for example, in the order of 200 mm, and having a thickness in the order of from 100 to 500 μm, for example, in the order of 200 μm. Blade structure 3 may have a length from 5 to 20 cm, for example, in the order of 10 cm. Mass 4 may have a weight in the order of from 10 to 250 g, for example, in the order of 50 g. Mass 4 may be attached to the blade(s) by gluing, welding, by screwing, or any other adapted means. Of course, the above dimensions are given as an example only. In practice, the dimensions of the system may be in the range from a few tenths of mm and a few tens of cm.

Various embodiments and variants have been described. These various embodiments and variants may be combined and other variants will occur to those skilled in the art. In particular, other geometries of frame 2 may be provided. Further, although a bimetal system forms a preferred embodiment due to its simplicity, more than two blades parallel to one another may be provided to form blade structure 3. Finally, the practical implementation of the described embodiments is within the abilities of those skilled in the art based on the functional indications given hereabove, in particular as to dimensions to be given to the different elements according to the application.

What is claimed is:

1. A mechanical vibration energy harvesting device comprising:
a bistable spring blade structure in a frame, and a sliding joint at the level of a wall of the frame between said structure and at least one mechanical-to-electrical conversion device external to the frame, the blade structure comprising at least two blades parallel to each other.

2. The device according to claim 1, wherein said sliding joint is obtained by an element sliding in said wall and coupling said structure to said conversion device.

3. The device according to claim 1, wherein said sliding joint is obtained by a deformation of said wall between said structure and said conversion device.

4. The device according to claim 1, wherein the conversion device is coupled to a fixed point with respect to the frame.

5. The device according to claim 1, wherein at least one mass is attached in the central portion of the blade structure.

6. The device according to claim 1, wherein the blade structure is buckled between the frame and said sliding joint.

7. The device according to claim 1, wherein the conversion device comprises a piezoelectric element in a direction approximately perpendicular to the direction of the blade structure.

8. The device according to claim 7, wherein the conversion device comprises a frame in the form of a double arch, the middles of the arches being respectively coupled to the sliding joint and to the fixed point.

9. An electric power generation system comprising:
equipment submitted to mechanical vibrations; and
the device according to claim 1.

10. The system according to claim 9, wherein the device is attached to the equipment.
